(19) United States
(12) Patent Application Publication
(10) Pub. No.: US 2024/0241042 A1
(43) Pub. Date: Jul. 18, 2024

(54) SUBSTRATE PROCESSING DEVICE AND METHOD FOR MEASURING PROCESS GAS TEMPERATURE AND CONCENTRATION

(71) Applicant: Tokyo Electron Limited, Minato-ku, Tokyo (JP)

(72) Inventor: Yuji OBATA, Nirasaki City, Yamanashi (JP)

(21) Appl. No.: 18/558,822

(22) PCT Filed: Apr. 28, 2022
(86) PCT No.: PCT/JP2022/019381

§ 371 Date: Nov. 3, 2023

(30) Foreign Application Priority Data
May 12, 2021 (JP) 2021-081140

(51) Int. Cl. G01N 21/31; G01K 11/12

(52) U.S. Cl. CPC G01N 21/3103; G01K 11/12; G01N 2201/06113

(57) ABSTRACT

Provided is a technique for using laser light to measure a temperature and concentration of a processing gas supplied to a processing space where a substrate processing is performed. A processing gas supply provided in an apparatus for processing a substrate supplies the processing gas to the processing space, and a light emitter emits laser light, having wavelengths that change within different wavelength ranges, to the processing space where the processing gas is supplied. A light receiver receives the laser light that has passed through the processing space, a temperature calculator calculates the temperature of the processing gas based on an absorption spectrum of laser light within each wavelength range, and a concentration calculator calculates the concentration of the processing gas based on an absorbance of laser light having a specific wavelength within the wavelength ranges.

### TECHNICAL FIELD

The present disclosure relates to an apparatus for processing a substrate and a method of measuring a temperature and concentration of a processing gas.

### BACKGROUND

For example, in apparatuses that perform a processing on a substrate such as a semiconductor wafer (hereinafter also referred to as a “wafer”), the processing is executed by supplying a processing gas to a processing space where the wafer is disposed. A temperature and concentration of the processing gas supplied to the processing space are important measurement parameters for controlling or designing the processing on the wafer.

For example, Patent Document 1 describes a technique of measuring a concentration of a gas supplied to a semiconductor manufacturing apparatus based on a result of irradiating the gas, which is flowing through a gas flow path, with two types of light having different wavelengths. In addition, Patent Document 2 describes a technique of measuring a concentration of a material gas, which is supplied to a substrate holding chamber of a film forming apparatus, by using an optical detection device.

### PRIOR ART DOCUMENTS

### Patent Documents

Patent Document 1: International Publication No. 2016/080532
Patent Document 2: Japanese Patent Laid-Open Publication No. 2012-122101

### SUMMARY

The present disclosures provides a technique of measuring a temperature and concentration of a processing gas, which is supplied to a processing space where a substrate processing is performed, by using laser light.

According to the present disclosure, an apparatus for performing a process on a substrate, includes: a processing container configured to accommodate the substrate and defining a processing space where the process is performed; a processing gas supply configured to supply a processing gas, which is for use in performing the process on the substrate processing or a process on a device disposed in the processing container, to the processing space; a light emitter configured to emit laser light to the processing space where the processing gas is supplied; a light source configured to supply, to the light emitter via a light waveguide, laser light of a wavelength that changes within a first wavelength range, which is a preset wavelength range, and laser light of a wavelength that changes within a second wavelength range, which is different from the first wavelength range; a light receiver configured to receive the laser light that has passed through the processing space; a temperature calculator configured to calculate a temperature of the processing gas based on an absorption spectrum of laser light within the first wavelength range received by the light receiver and an absorption spectrum of laser light within the second wavelength range received by the light receiver; and a concentration calculator configured to calculate a concentration of the processing gas based on an absorbance of laser light of a specific wavelength within the first wavelength range or within the second wavelength range.

According to the present disclosure, it is possible to measure a temperature and concentration of a processing gas, which is supplied to a processing space where a substrate processing is performed, by using laser light.

### BRIEF DESCRIPTION OF DRAWINGS

FIG. 1 is a longitudinal cross-sectional side view of a wafer processing apparatus according to the present disclosure.

FIG. 2 is a schematic view of a stage and a gas shower head, which are provided in the wafer processing apparatus.

FIG. 3A is a plan view illustrating a first layout example of a light emitting/receiving set.

FIG. 3B is a plan view illustrating a second layout example of the light emitting/receiving set.

FIG. 4 is an enlarged schematic view of the stage provided with a reflector.

FIG. 5 is a longitudinal cross-sectional side view of a wafer processing apparatus according to another configuration example.

### DETAILED DESCRIPTION

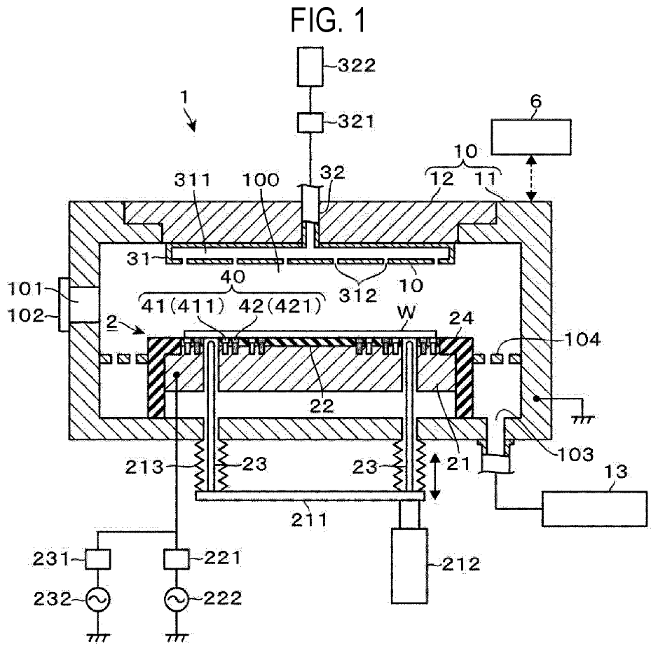

Hereinafter, a configuration example of an apparatus for processing a substrate (a wafer processing apparatus 1) according to an embodiment of the present disclosure will be described with reference to FIGS. 1 to 4.

The wafer processing apparatus 1 of this example is configured as an apparatus that executes a film forming process by supplying a plasmarized processing gas to an upper surface of a wafer W as a substrate.

As illustrated in the longitudinal cross-sectional side view of FIG. 1, the wafer processing apparatus 1 includes a cylindrical container main body 11 made of a conductive material (for example, having an inner wall surface made of anodized aluminum), and the container main body 11 is electrically grounded. An opening is formed in an upper surface of the container main body 11, and the opening is airtightly closed by a ceiling plate 12. The container main body 11 and the ceiling plate 12 constitute a processing container 10 configured to accommodate the wafer W therein. An internal space of the processing container 10 serves as a processing space 100 for the wafer W.

In addition, a sidewall of the processing container 10 is provided with a loading/unloading port 101 for loading and unloading the wafer W and a gate valve 102 configured to open and close the loading/unloading port 101.

A stage 2 configured to place the wafer W thereon is provided at a lower portion in the processing space 100 so as to face the ceiling plate 12. The stage 2 includes a stage main body 21 made of a conductive metal material (for example, having a surface made of anodized aluminum). A heater (not illustrated) configured by, for example, a resistance heating element is provided in the stage 2.

An upper surface of the stage main body 21 is provided with an electrostatic chuck 22 formed by disposing a chuck electrode (not illustrated) in a ceramic layer. The electrostatic chuck 22 is capable of switching between attractively hold and release of the wafer W by a supply and cut-off of power from a DC power supply (not illustrated). The stage main body 21 is accommodated in a cover 24 made of an insulating material, and is installed on a bottom surface of the container main body 11 via the cover 24.

In addition, the stage 2 includes three or more lifting pins 23 for delivering the wafer W with respect to an external substrate transfer mechanism (not illustrated) which enters the processing space 100 via the loading/unloading port 101. These lifting pins 23 function to lift and transfer the wafer W between an attractively hold position on the electrostatic chuck 22 and a transfer position above the attractively hold position. Each lifting pin 23 is provided to pass through the stage main body 21 and a bottom plate of the container main body 11 in a vertical direction, and lower end portions of the lifting pins 23 are connected to a common lifting plate 211 provided outside the container main body 11.

The lifting plate 211 is also connected to a drive 212. The lifting plate 211 moves vertically by the drive 212, causing upper end portions of the lifting pins 23 to protrude and retract from the electrostatic chuck 22. By this operation, the lifting and transferring the wafer W between the attractively hold position and the transfer position is performed. In addition, a bellows 213 is provided between the bottom plate of the container main body 11, through which each lifting pin 23 passes, and the lifting plate 211, so that airtightness inside the container main body 11 (processing space 100) is maintained.

A first radio frequency power supply 232 is connected to the stage 2 via a matcher 231. Radio frequency power is supplied from the first radio frequency power supply 232 to the stage 2 via the matcher 231. Thus, a processing gas supplied to the processing space 100 is plasmarized through capacitive coupling with a shower head 31 to be described later, so that a desired film forming process can be performed.

In addition, means for plasmarizing the processing gas is not limited to adopting capacitively coupled parallel plates. For example, plasma may be generated using an inductively coupled antenna, or may be generated by supplying microwaves from a microwave antenna to the processing gas.

In addition, a second radio frequency power supply 222 is connected to the stage 2 via a matcher 221. The second radio frequency power supply 222 applies radio frequency power for biasing to the stage 2. By self-bias generated by this radio frequency power for biasing, ions in the plasma generated in the processing space 100 can be drawn into the wafer W.

In addition, as illustrated in FIG. 1, an exhaust port 103 is formed in the bottom surface of the container main body 11, and a vacuum exhauster 13, which includes a vacuum pump and the like, is connected to the exhaust port 103. An interior of the processing space 100 is vacuum-evacuated by the vacuum exhauster 13 until it reaches a pressure required during a processing. In addition, in order to ensure that the gas supplied into the processing space 100 flows uniformly toward a periphery of the stage 2, a rectifying plate 104 having a plurality of small holes formed therein by punching may be disposed between a side peripheral surface of the stage 2 (cover 24) and the inner wall surface of the container main body 11.

As illustrated in FIG. 1, the shower head 31 configured to supply the processing gas into the processing space 100 is provided on a side of a lower surface of the ceiling plate 12. A flat diffusion space 311, which is configured to supply the processing gas and the like toward an entire surface of the wafer W attractively held by the electrostatic chuck 22, is defined in the shower head 31. A plurality of gas supply ports 312 is formed on a lower surface of the shower head 31, so that a gas diffused in the diffusion space 311 is distributed and supplied toward the processing space 100 via the gas supply ports 312.

In addition, a gas supply line 32 in communication with the diffusion space 311 is connected to an upper surface of the shower head 31. A regulator 321, which includes an on-off valve or a flow controller (none of which is illustrated) for performing the supply and cut-off of the processing gas or a flow rate control of the processing gas, and a processing gas source 322, which stores a raw material gas therein, are provided on an upstream side of the gas supply line 32. The shower head 31, the gas supply line 32, the regulator 321, and the processing gas source 322 constitute a processing gas supply in this example.

The film forming process performed in the wafer processing apparatus 1 may be plasma chemical vapor deposition (plasma CVD). In plasma CVD, processing gases for film formation such as a raw material gas and a reactive gas are continuously supplied to the processing space 100, and the gases are activated by plasma to perform the film forming process on the wafer W.

In addition, the film forming process may be performed by plasma atomic layer deposition (plasma ALD). In plasma ALD, adsorption of a raw material gas onto the wafer W and reaction between the adsorbed raw material gas and a reactive gas activated by plasma, for example, are alternately repeated in the processing space 100, so that layers of a material of a film to be formed on the wafer W are deposited. In the case of ALD, the shower head 31 is connected to a plurality of regulators 321 or processing gas sources 322 for supplying the precursor gas, the reactive gas, and a purge gas.

In addition, as illustrated in FIG. 1, the wafer processing apparatus 1 is provided with a controller 6. The controller 6 is configured by a computer having a central processing unit (CPU) and a storage (none of which is illustrated). A program, which includes a group of steps (instructions) to output control signals for vacuum-evacuating the processing space 100 where the wafer W is disposed and processing the wafer W by applying the radio frequency power to the stage 2 to plasmarize the processing gas, is recorded in the storage. This program is stored in a storage medium, for example, a hard disk, a compact disk, a magnet optical disk, or a memory card, and is installed from the storage medium into the storage.

In addition, the wafer processing apparatus 1 according to the present embodiment includes a mechanism for measuring a temperature and concentration of the processing gas supplied from the processing gas supply to the processing space 100.

As a method of measuring the concentration, well-known absorption spectrophotometry is used. In absorption spectrophotometry, the processing gas supplied into the processing space 100 is irradiated with light of a wavelength absorbed by the processing gas, and the concentration of the processing gas is specified based on a ratio between an intensity of incident light and an intensity of light after passing through the processing space 100.

In addition, in the wafer processing apparatus 1 of this example, similar to the concentration measurement, absorbance of light to the processing gas is also used in temperature measurement. A gas may have a plurality of absorption wavelengths. In addition, an actual gas exhibits an absorption spectrum in which an absorbance is highest at an absorption wavelength and gradually decreases as a distance from the absorption wavelength increases within a wavelength range centered on the absorption wavelength.

It is known that there is a correspondence between an area ratio or a peak intensity ratio of two absorption spectra and a temperature of a gas, and a technique of measuring a temperature of a gas using this correspondence has also been proposed (e.g., Japanese Patent Laid-Open Publication No. 2000-74830 and Japanese Patent Laid-Open Publication No. 2020-6724).

The wafer processing apparatus 1 of this example calculates the temperature and the concentration of the processing gas based on an absorption spectrum obtained by irradiating the processing gas supplied into the processing space 100 with laser light within a predetermined wavelength range.

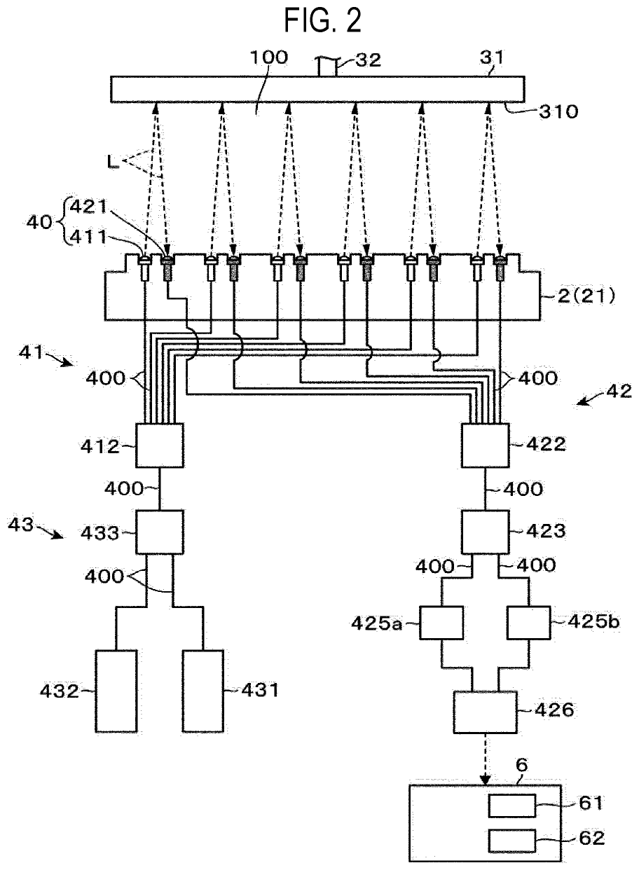

In order to perform the temperature and concentration measurements as described above, as illustrated in FIG. 2, the wafer processing apparatus 1 includes a light emitter 41 that emits laser light to the processing space 100, a light source 43 that supplies laser light to the light emitter 41, and a light receiver 42 that receives the laser light that has passed through the processing space 100.

The light emitter 41 includes a light emitting lens 411 from which laser light is discharged, and an optical fiber 400 that serves as a light waveguide via which the laser light is supplied to the light emitting lens 411. As illustrated in FIGS. 1 and 2, in the wafer processing apparatus 1 of this example, the light emitting lens 411 is provided on the stage 2 in the processing container 10. In addition, a plurality of light emitting lenses 411 is provided on the stage 2.

Each light emitting lens 411 is oriented to emit laser light from a side of the upper surface of the stage 2 toward an opposing surface 310 of the shower head 31 that is disposed to face the upper surface of the stage 2. In addition, in order to prevent the light emitting lens 411 from being contaminated by the processing gas, a cover formed of a member that transmits laser light may be provided on a side of an upper surface of the light emitting lens 411. Planar arrangement of the plurality of light emitting lenses 411 will be described later.

Each light emitting lens 411 is connected to a common changeover switch 412 via the optical fiber 400. The changeover switch 412 functions to change the light emitting lens 411 that serves as a destination of the laser light supplied from the light source 43.

The light source 43 includes a first semiconductor laser device 431, a second semiconductor laser device 432, and a coupler 433.

Each of the first and second semiconductor laser devices 431 and 432 generates laser light of a desired wavelength by using a semiconductor diode. The first semiconductor laser device 431 can change a wavelength of laser light within a preset wavelength range (first wavelength range) centered on an absorption wavelength λ1 of the processing gas. In addition, similarly, the second semiconductor laser device 432 cab change a wavelength of laser light within a preset wavelength range (second wavelength range) centered on an absorption wavelength λ2 different from the aforementioned first absorption wavelength λ1.

There is no particular limitations on an example of setting the absorption wavelengths λ1 and λ2. Laser light of a wavelength within a range of invisible light such as infrared light or ultraviolet light may be used, or laser light of a wavelength within a range of visible light may be used.

The first wavelength range and the second wavelength range are set to include a region where the absorbance of both tails of each absorption spectrum becomes sufficiently small and reaches a baseline of the absorbance of the processing gas.

In addition, each of the first and second semiconductor laser devices 431 and 432 may be configured to output, when obtaining the absorption spectrum, reference light indicating an intensity of laser light with zero absorbance, or laser light used as etalon signals for a filter toward a main body 426 of a photometer to be described later.

The laser lights supplied from the first and second semiconductor laser devices 431 and 432 are coupled by the coupler 433, and then input to the changeover switch 412 via the optical fiber 400 to be supplied to a selected light emitting lens 411.

Next, the light receiver 42 includes a light receiving lens 421 on which laser light is incident and the optical fiber 400 that guides the laser light received via the light receiving lens 421. As illustrated in FIGS. 1 and 2, in the wafer processing apparatus 1 of this example, similar to the light emitting lens 411, the light receiving lens 421 is also provided on the stage 2. In addition, the same number of light receiving lenses 421 as the light emitting lenses 411 are provided on the stage 2.

Each light receiving lens 421 is oriented to receive laser light reflected from the opposing surface 310 of the shower head 31. In addition, similar to the case of the light emitting lens 411, a cover formed of a member that transmits laser light may be provided on a side of an upper surface of the light receiving lens 421. Planar arrangement of a plurality of light receiving lenses 421 will be described later. In addition, in FIGS. 1 to 3A and 3B, the light receiving lens 421 is shaded in gray.

Each light receiving lens 421 is connected to a common changeover switch 422 via the optical fiber 400. The changeover switch 422 functions to change the light receiving lens 421 that serves as a target from which the laser light is extracted.

The light emitting lenses 411 and the light receiving lenses 421, which are provided in equal numbers on the stage 2, are mutually correlated via respective optical paths L of laser light, constituting light emitting/receiving sets 40. That is, the light emitting lens 411 and the light receiving lens 421 constituting the common light emitting/receiving set 40 are disposed to be located at one end and the other end of the optical path L of laser light. With this configuration, the laser light emitted from the selected light emitting lens 411 may be reflected by the opposing surface 310 of the shower head 31, and then received by the light receiving lens 421 correlated with the light emitting lens 411.

Here, in order to reflect laser light on the opposing surface 310, the shower head 31 may be made of a metal, or a surface of the shower head 31 made of a ceramic may be coated with silicon.

By providing the plurality of light emitting/receiving sets 40 at different locations on the stage 2, the laser light can pass through different regions in the processing space 100, and the temperature and the concentration of the processing gas in these regions can be measured. By measuring the temperature and the concentration of the processing gas in the plurality of different regions, a temperature distribution and a concentration distribution of the processing gas in the processing space 100 can be specified.

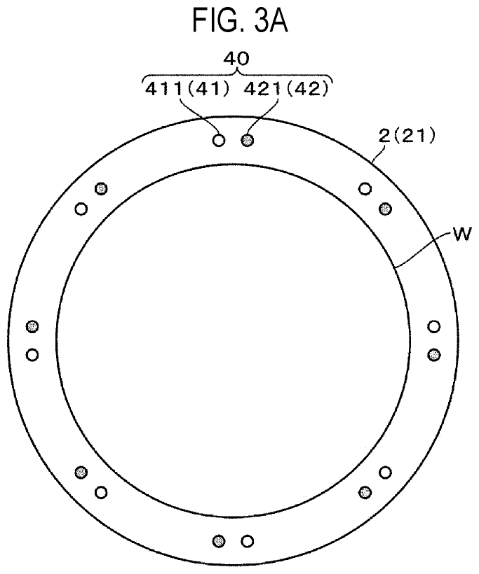

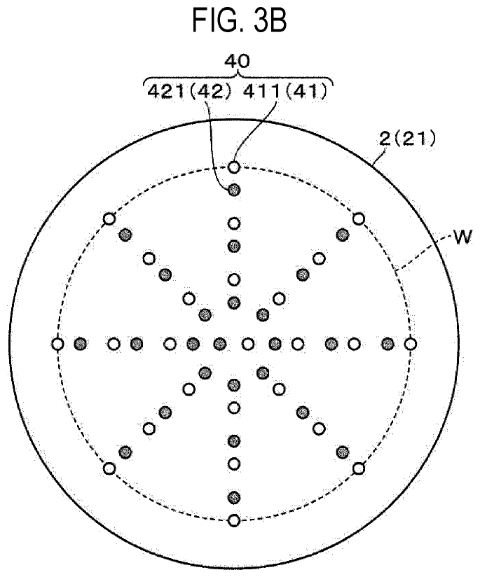

FIGS. 3A and 3B illustrate variations in arrangement of the plurality of light emitting/receiving sets 40 on the stage 2.

During a period when a processing using the processing gas is being performed, the wafer W is placed on the upper surface of the stage 2. Therefore, when the light emitting/receiving set 40 is arranged in a placement region where the wafer W is placed, the light emitting lens 411 and the light receiving lens 421 are covered by the wafer W during the processing period.

FIG. 3A illustrates an example in which the light emitting/receiving sets 40 are disposed around the placement region for the wafer W in order to prevent the light emitting lenses 411 and the light receiving lenses 421 from being covered by the wafer W. In the example illustrated in FIG. 3A, the plurality of light emitting/receiving sets 40 is disposed equidistantly along a circumferential direction of the circular stage 2 in a plan view.

On the other hand, as illustrated in FIG. 3B, the light emitting/receiving sets 40 may be disposed in the region where the wafer W is placed. In this example, the plurality of light emitting/receiving sets 40 is disposed to be arranged in a radial direction of the placement region for the circular wafer W.

When the light emitting/receiving sets 40 are provided in the placement region for the wafer W, for example, the temperature and the concentration of the processing gas may be measured by, for example, emitting laser light from the light emitting lens 411 during a period when the wafer W is not placed on the stage 2.

In addition, at a heating temperature of, for example, 0 degrees C. to 270 degrees C., the wafer W made of silicon transmits light having a wavelength within a range of 1.8 μm to 6.0 μm. When the absorption wavelength of the processing gas falls within this wavelength range, it is possible to measure the temperature and the concentration of the processing gas while the wafer W is placed on the stage 2, by emitting laser light having a wavelength that passes through the wafer W.

Returning to the description of FIG. 2, the laser light output from the light receiver 42 via the changeover switch 422 is split into laser light within the first wavelength range and laser light within the second wavelength range by a splitter 423 having an optical filter. Thereafter, the laser lights within the wavelength ranges are converted into electrical signals by photodiodes 425a and 425b, respectively, and then input to the main body 426 of the photometer.

In the main body 426, absorption spectrums that represent changes in absorbance with respect to the wavelengths of the laser lights can be obtained, respectively, by comparison with the intensities of the reference lights supplied from the first and second semiconductor laser devices 431 and 432.

The main body 426 outputs information that specifies the absorption spectrums to the controller 6 which has been already described.

The controller 6 in this example has functions of a temperature calculator 61 and a concentration calculator 62.

The temperature calculator 61 calculates the temperature of the processing gas based on a correspondence between the temperature of the processing gas and a ratio of areas or peak intensities between the absorption spectrum within the first wavelength range and the absorption spectrum within the second wavelength range. The correspondence between the temperature of the processing gas and the aforementioned area ratio or peak intensity ratio is acquired in advance through experiments and the like, and is stored as a table or function in the storage of the controller 6.

The concentration calculator 62 calculates the concentration of the processing gas based on an absorbance of laser light at a specific wavelength within the first and second wavelength ranges, for example, at a maximum peak wavelength of the absorption spectrum. As for a concentration calculation method, the well-known Lambert-Beer law may be used as an example.

Operations of the wafer processing apparatus 1 having the above-described configuration will be described.

First, the gate valve 102 is open, and the wafer W as a processing target is loaded into the processing container 10 using an external transfer mechanism (not illustrated). Thereafter, the wafer W is raised and received from a side of a lower surface thereof by the lifting pins 23, and the transfer mechanism is retracted to the outside of the apparatus and the gate valve 102 is closed. Subsequently, the lifting pins 23 are lowered to place the wafer W on the stage 2.

The stage 2 is heated to a preset temperature by the heater (not illustrated) provided in the stage 2, and the wafer W is heated to a processing temperature by heat transfer from the stage 2. Here, a region where the light emitting lenses 411, the light receiving lenses 421, or the optical fibers 400 are disposed may be surrounded with an insulator to avoid influence of heating by the heater on these devices.

When the wafer W is placed on the stage 2, the interior of the processing container 10 (processing space 100) is vacuum-evacuated by the vacuum exhauster 13. Subsequently, the processing gas is supplied to the processing space 100 to perform the film forming process. That is, when performing the film forming process by plasma CVD, the raw material gas and the reactive gas are continuously supplied, and radio frequency power is applied to the stage 2 from the radio frequency power supply 222 and the radio frequency power supply 232. Thus, the gases are plasmarized, and a reaction to form a film material proceeds. As a result, the film material is deposited on the surface of the wafer W to form a desired film thereon.

In addition, when performing the film forming process by plasma ALD, supplying the raw material gas and the reactive gas and exhausting these gases (including a case where the exhaust is performed while a purge gas is supplied) are sequentially repeated. In addition, during a period when the processing gas to be plasmarized is supplied, radio frequency power is applied to the stage 2 so that the processing gas is plasmarized and a reaction to form a film material proceeds. As a result, layers of the film material formed on the surface of the wafer W are stacked, and a desired film is formed.

At this time, in a case of in-situ measurement of the temperature and the concentration of the processing gas using laser light, an operation of measuring the temperature and the concentration of the processing gas is executed while the film forming process is being executed. In this case, the wafer W is continuously placed on the stage 2. Therefore, the measurement may be performed using the light emitting/receiving sets 40 disposed around the placement region for the wafer W, as illustrated in FIG. 3A. In addition, the measurement may be performed using the light emitting/receiving sets 40 disposed in the placement region for the wafer W, as illustrated in FIG. 3B, and using laser light having a wavelength that passes through the wafer W.

In addition, when using the plasmarized gas, there may be a case where it is difficult to measure the temperature and concentration of the processing gas using the absorption spectrum of laser light. In this case, a period during which temperature and concentration measurements are performed without plasmarizing the processing gas may be provided after supplying the processing gas.

When measuring the temperature and concentration of the processing gas, one or a plurality of (or all) light emitting/receiving sets 40 are selected, which are disposed at locations where laser light passes through a region desired to perform the temperature and concentration measurements therein. In addition, the selected light emitting/receiving sets 40 are connected to the light source 43 and the main body 426 using the changeover switches 412 and 422. Thereafter, the first and second semiconductor laser devices 431 and 432 supply laser lights while gradually changing wavelengths of the laser lights within the first and second wavelength ranges (scanning operation).

The laser lights are coupled in the coupler 433, and then supplied to the light emitting lens 411 selected by the changeover switch 412 and emitted to the processing space 100. The laser light passes through the processing space 100 where the processing gas is supplied, and is reflected by the opposing surface 310 of the shower head 31. Thereafter, the laser light reaches the light receiving lens 421 selected by the changeover switch 422. During a period when the laser light passes through the optical path described above, the laser light is absorbed by the processing gas and decreases in intensity.

The laser light received by the light receiving lens 421 is split into laser lights within respective wavelength ranges by the splitter 423. Thereafter, the laser lights are converted into electrical signals with voltages corresponding to intensities of the laser lights by the photodiodes 425a and 425b, and then input to the main body 426.

In the main body 426, absorption spectra for the first and second wavelength ranges, respectively, are created by, for example, comparison with the intensities of the reference lights.

Data representing the created absorption spectra is output to the controller 6, and based on the aforementioned calculation methods, the temperature of the processing gas is calculated by the temperature calculator 61 and the concentration of the processing gas is calculated by the concentration calculator 62.

When a plurality of light emitting/receiving sets 40 are used for measurement, the selected light emitting/receiving sets 40 are sequentially switched on and off to repeatedly execute the above-described measurement operation.

Based on the measured temperature and concentration of the processing gas, a supply amount of the processing gas, an amount of vacuum evacuation by the vacuum exhauster 13, and a temperature of the processing gas by a temperature regulation mechanism provided in, for example, the processing gas source 322 may be regulated. In this case, the film forming process on the wafer W may be executed after the regulation described above.

When a predetermined time elapses and the film forming process is completed, the supplying the processing gas, the applying the radio frequency power, and the heating the wafer W are stopped. Thereafter, the internal pressure of the processing container 10 is regulated, and then, the wafer W after the film formation is unloaded from the processing container 10 in a reverse order of loading the wafer W.

In addition, there may be a case where it is difficult to measure the temperature and concentration of the processing gas during a period when the wafer W is being processes. Therefore, a period during which the processing gas is supplied to the processing space 100 may be set within a period when the wafer W is not being processes, and the temperature and concentration may be measured during thus set period. In this case, even when using the light emitting/receiving sets 40 disposed in the placement region for the wafer Was illustrated in FIG. 3B, it is not essential to use laser light having a wavelength that passes through the wafer W. In addition, in this case as well, of course, it is possible to measure the temperature and concentration of the processing gas using the lighting emitting/receiving sets 40 disposed in the region as illustrated in FIG. 3A.

According to the embodiment described above, it is possible to measure the temperature and concentration of the processing gas simultaneously by acquiring absorption profiles of laser lights within two different wavelength ranges in the processing space 100 where the processing gas is supplied.

In particular, by using the light emitting/receiving sets 40 disposed at a plurality of different locations, it is possible to specify distributions of the temperature and concentration of the processing gas in the processing space 100.

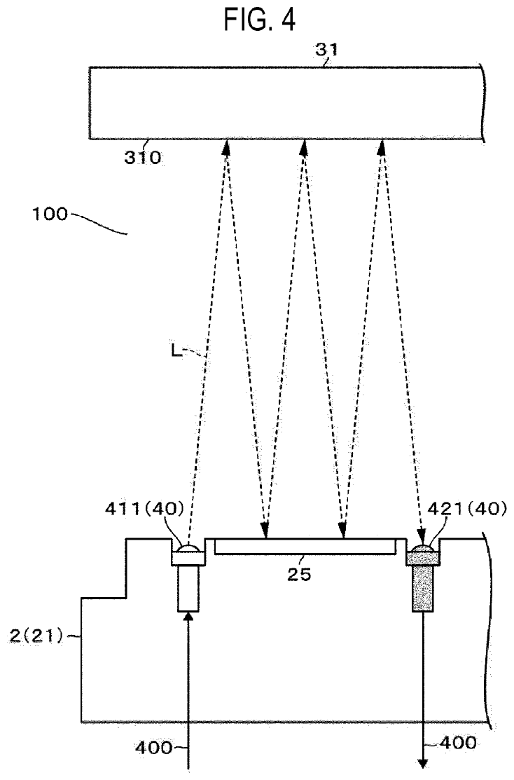

FIG. 4 illustrates a modification of a configuration in which the light emitting/receiving set 40 is provided on the stage 2 as described above with reference to FIGS. 1 and 2. In this example, a reflector 25 is provided on the upper surface of the stage 2 so that laser light reflected from the opposing surface 310 of the shower head 31 is reflected back toward the opposing surface 310 by the reflector 25.

With this configuration, as illustrated in FIG. 4, the laser light emitted from the light emitting lens 411 may be reflected multiple times between the opposing surface 310 on a side of the shower head 31 and the reflector 25 on a side of the stage 2. By causing the laser light to be reflected multiple times, a length of the optical path L increases, and thus sensitivity of temperature and concentration measurements of the processing gas can be improved.

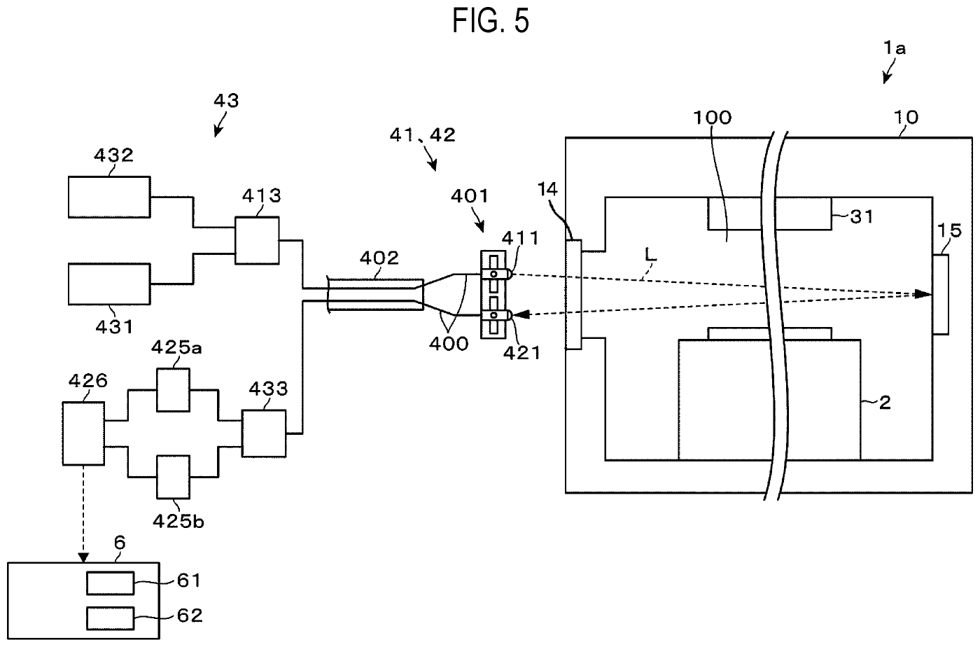

Next, a configuration example of a wafer processing apparatus 1a according to a second embodiment will be described with reference to FIG. 5. In FIG. 5, components common to the configurations described with reference to FIGS. 1 to 4 are designated by the same reference numerals used in those drawings.

In the wafer processing apparatus 1a illustrated in FIG. 5, the light emitting lens 411 constituting the light emitter 41 and the light receiving lens 421 constituting the light receiver 42 are provided outside the processing container 10 (processing space 100). A window 14 configured to transmit laser light is provided on the sidewall of the processing container 10 at a location different from the region where the loading/unloading port 101 is formed.

The light emitting lens 411 and the light receiving lens 421 are disposed at locations facing the window 14, while being held by a collimator 401. On the other hand, a reflector 15 is provided on the inner wall surface of the processing container 10, which is opposite to the light emitting lens 411 and the light receiving lens 421 with the window 14 interposed therebetween. In addition, in this example, connection between the light emitter 41 and the light source 43 and connection between the light receiver 42 and devices on a side of the main body 426 are made using a two-core cable 402.

With the above-described arrangement, after entering the processing space 100 via the window 14, the laser light emitted from the light emitting lens 411 is reflected by the reflector 15, passes through the processing space 100 and the window 14, and then is received by the light receiving lens 421.

In the configuration of the wafer processing apparatus 1a of this example as well, it is possible to measure the temperature and concentration of the processing gas simultaneously by acquiring absorption profiles of laser lights within two different wavelength ranges in the processing space 100 where the processing gas is supplied.

In addition, the window 14 illustrated in FIG. 5 is a common window that serves as both of a light emitting window for introducing the laser light emitted from the light emitting lens 411 into the processing space 100 and a light receiving window for receiving the laser light that has passed through the processing space 100 by the light receiving lens 421.

In addition, unlike the example illustrated in FIG. 5, for example, the light emitting lens 411 and the light receiving lens 421 may be separately disposed at locations opposite to each other with the processing container 10 interposed therebetween. In this case, the light emitting window for introducing the laser light into the processing space 100 may be provided on a wall surface of the processing container 10 facing the light emitting lens 411, and the light receiving window for receiving the laser light that has passed through the processing space 100 may be provided on a wall surface facing the light receiving lens 421.

In the method described above, the processing gas, which is a target of the temperature and concentration measurements, is not limited to the raw material gas or the reactive gas that are used during the film forming process. It may be an etching gas for use in an etching process for the substrate, an ashing gas for use in an ashing removal process of a resist film applied to the substrate, or a cleaning gas for performing, for example, a cleaning process as a processing of a device disposed in the processing space 100.

In addition, the substrate on which a process using the processing gas is not limited to the semiconductor wafer as an example. For example, it may be a glass substrate of a flat panel display (FPD).

The embodiments disclosed herein should be considered to be exemplary and not limitative in all respects. The above embodiments may be omitted, replaced or modified in various embodiments without departing from the scope of the appended claims and their gist.

### EXPLANATION OF REFERENCE NUMERALS

L: optical path, W: wafer, 1, 1a: wafer processing apparatus, 100: processing space, 10: processing container, 31: shower head, 411: light emitting lens, 421: light receiving lens, 6: controller, 61: temperature calculator, 62: concentration calculator

1-11. (canceled)

12. An apparatus for performing a process on a substrate, comprising:
a processing container configured to accommodate the substrate and defining a processing space where the process is performed;
a processing gas supply configured to supply a processing gas, which is for use in performing the process on the substrate or a process on a device disposed in the processing container, to the processing space;
a light emitter configured to emit laser light to the processing space where the processing gas is supplied;
a light source configured to supply, to the light emitter via a light waveguide, laser light of a wavelength that changes within a first wavelength range, which is a preset wavelength range, and laser light of a wavelength that changes within a second wavelength range, which is different from the first wavelength range;
a light receiver configured to receive the laser light that has passed through the processing space;
a temperature calculator configured to calculate a temperature of the processing gas based on an absorption spectrum of the laser light within the first wavelength range received by the light receiver and an absorption spectrum of the laser light within the second wavelength range received by the light receiver; and
a concentration calculator configured to calculate a concentration of the processing gas based on an absorbance of laser light of a specific wavelength within the first wavelength range or within the second wavelength range.

13. The apparatus of claim 12, wherein the processing space is provided with a stage on which the substrate is placed, and a gas shower head having an opposing surface facing the stage and a gas supply port formed in the opposing surface to supply the processing gas to the processing space, and
wherein the light emitter and the light receiver are disposed on the stage such that the laser light emitted from the light emitter is reflected by the opposing surface and is then received by the light receiver.

14. The apparatus of claim 13, wherein the stage is provided with a plurality of light emitting/receiving sets, each of which includes the light emitter and the light receiver in association with each other so that the laser light passes through different regions within the processing space, and
wherein the temperature calculator and the concentration calculator calculate the temperature and the concentration of the processing gas in a region where the laser light emitted and received by each of the light emitting/receiving sets passes.

15. The apparatus of claim 14, wherein the stage is further provided with a reflector that reflects the laser light reflected from the opposing surface back toward the opposing surface.

16. The apparatus of claim 15, wherein the light emitter and the light receiver are provided around a region of the stage where the substrate is placed.

17. The apparatus of claim 13, wherein the stage is further provided with a reflector that reflects the laser light reflected from the opposing surface back toward the opposing surface.

18. The apparatus of claim 13, wherein the light emitter and the light receiver are provided around a region of the stage where the substrate is placed.

19. The apparatus of claim 13, wherein the light emitter and the light receiver are provided in a region of the stage where the substrate is placed, and the light emitter emits the laser light during a period when the substrate is not placed on the stage.

20. The apparatus of claim 13, wherein the light emitter and the light receiver are provided in a region of the stage where the substrate is placed, and the light source supplies, to the light emitter, laser light of a wavelength that passes through the substrate.

21. The apparatus of claim 12, wherein the light emitter and the light receiver are provided outside the processing container, and the processing container is provided with a light emitting window configured to introduce the laser light emitted from the light emitter into the processing space and a light receiving window configured to receive the laser light that has passed through the processing space by the light receiver.

22. The apparatus of claim 21, wherein a common window serves as both of the light emitting window and the light receiving window, and a reflector that reflects the laser light introduced into the processing space via the common window back toward the common window is provided in the processing space.

23. A method of measuring a temperature and a concentration of a processing gas for a process on a substrate, the method comprising:
supplying the processing gas, which is for use in performing the process on the substrate or a process on a device disposed in a processing container, to a processing space where the process is performed;
emitting, to the processing space where the processing gas is supplied, laser light of a wavelength that changes within a first wavelength range, which is a preset wavelength range, and laser light of a wavelength that changes within a second wavelength range, which is different from the first wavelength range;
receiving the laser light that has passed through the processing space;
calculating the temperature of the processing gas based on an absorption spectrum of the received laser light within the first wavelength range and an absorption spectrum of the received laser light within the second wavelength range; and
calculating the concentration of the processing gas based on an absorbance of laser light of a specific wavelength within the first wavelength range or within the second wavelength range.

24. The method of claim 23, wherein in the emitting the laser light and in the receiving the laser light, emission and reception of the laser light is performed a plurality of times to cause the laser light to pass through different regions in the processing space, and
wherein in the calculating the temperature and in the calculating the concentration, the temperature and the concentration of the processing gas are calculated in each region where the laser light passes.
